(19) United States
(12) Patent Application Publication
(10) Pub. No.: US 2009/0142672 A1
(43) Pub. Date: Jun. 4, 2009

(54) OPTICAL RECORDING COMPOSITION AND HOLOGRAPHIC RECORDING MEDIUM

(75) Inventor: Satoru YAMADA, Kangawa (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/275,443

(22) Filed: Nov. 21, 2008

(30) Foreign Application Priority Data
Nov. 30, 2007 (JP) 2007-310375
Feb. 18, 2008 (JP) 2008-035530

(51) Int. Cl. G03F 7/004; C07F 9/32

(52) U.S. Cl. 430/2; 568/15; 546/22; 546/21

(57) ABSTRACT

The present invention provides an optical recording composition comprising a compound denoted by general formula (I) and a holographic recording medium comprising a recording layer, wherein the recording layer comprises a compound denoted by general formula (I).

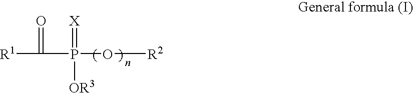

In general formula (I), each of R¹, R², and R³ independently denotes an alkyl group, aryl group, or heterocyclic group, X denotes an oxygen atom or sulfur atom, and n denotes 0 or 1.

### CROSS-REFERENCE TO RELATED APPLICATIONS

This application claims the benefit of priority under 35 USC 119 to Japanese Patent Application No. 2007-310375 filed on Nov. 30, 2007 and Japanese Patent Application No. 2008-35530 filed on Feb. 18, 2008, which are expressly incorporated herein by reference in their entirety.

### BACKGROUND OF THE INVENTION

1. Field of the Invention

The present invention relates to an optical recording composition comprising a specific phosphorus compound, and more particularly, to an optical recording composition suited to the manufacturing of a holographic recording medium permitting the writing of information, for example, with a 405 nm laser, particularly a volume holographic recording medium having a relatively thick recording layer. The present invention further relates to a holographic recording medium comprising a recording layer comprising the phosphorus compound.

2. Discussion of the Background

Holographic optical recording media based on the principle of the holograph have been developed. Recording of information on holographic optical recording media is carried out by superposing an informing light containing image information and a reference light in a recording layer comprised of a photosensitive composition to write an interference fringe thus formed in the recording layer. During the reproduction of information, a reference light is directed at a prescribed angle into the recording layer in which the information has been recorded, causing optical diffraction of the reference light by the interference fringe which has been formed, reproducing the informing light.

In recent years, volume holography, and, more particularly, digital volume holography, have been developed to practical levels for ultrahigh-density optical recording and have been garnering attention. Volume holography is a method of writing interference fringes three-dimensionally by also actively utilizing the direction of thickness of an optical recording medium. It is advantageous in that increasing the thickness permits greater diffraction efficiency and multiplexed recording increases the recording capacity. Digital volume holography is a computer-oriented holographic recording method in which the image data being recorded are limited to a binary digital pattern while employing a recording medium and recording system similar to those of volume holography. In digital volume holography, for example, image information such as an analog drawing is first digitized and then expanded into two-dimensional digital pattern information, which is recorded as image information. During reproduction, the digital pattern information is read and decoded to restore the original image information, which is displayed. Thus, even when the signal-to-noise (S/N) ratio deteriorates somewhat during reproduction, by conducting differential detection or conducting error correction by encoding the two-dimensional data, it is possible to reproduce the original data in an extremely faithful manner (see Japanese Unexamined Patent Publication (KOKAI) Heisei No. 11-311936 or English language family member US 2002/0114027 A1, which are expressly incorporated herein by reference in their entirety).

Photopolymer-type holographic optical recording media normally comprise a recording layer formed with a composition containing a polymerizable monomer and a photopolymerization initiator. For example, U.S. Pat. No. 6,780,546, which is expressly incorporated herein by reference in its entirety, discloses a technique of writing with a 405 nm laser employing photopolymerization initiators in the form of acylphosphine oxide and bisacylphosphine oxide compounds. These optical polymerization initiators are available as commercial products (specifically, Darocure TPO (made by Ciba Specialty Chemicals) and Irg-819 (made by Ciba Specialty Chemicals)).

In photopolymer-type holographic recording media, the recording monomer is polymerized by irradiation with an informing light and an interference light, thereby forming an interference image within the recording layer. A fixing light is then irradiated into the recording layer in which the interference image has been formed to fix the interference image. When a large quantity of recording monomer remains at the conclusion of the formation and fixing (recording reaction) of the interference image, the polymerization reaction advances further when the recording medium in which the interference image has been formed is exposed to bright light, creating a risk that the data that have been stored will be compromised over time. Thus, to enhance recording retention capacity, it is desirable for little recording monomer to remain at the conclusion of the recording reaction. There has been a need for the designing of such a system. However, the photopolymerization initiator described in U.S. Pat. No. 6,780,546 has high absorbance; the more that is added, the less the transmittance in the direction of depth, resulting in a drop in recording sensitivity. However, enhanced sensitivity is desirable in volume holography such as the above-described digital volume holography. Accordingly, the quantity of the photopolymerization initiator described in U.S. Pat. No. 6,780,546 that can be added to obtain good recording sensitivity in volume holography is limited. Thus, the addition of an inadequate quantity of photopolymerization initiator sometimes precludes a good polymerization reaction, resulting in monomer remaining following the recording reaction.

### SUMMARY OF THE INVENTION

An aspect of the present invention provides for an optical recording composition that is suited to digital volume holography, that has good recording retention capacity, in which the quantity of recording monomer remaining at the conclusion of the reaction is low, and that affords good recording sensitivity, and a holographic recording medium permitting ultrahigh density optical recording that can be formed with the above composition.

As the result of extensive research, the present inventor discovered that the above-stated optical recording composition was obtained with a specific phosphorus compound denoted by general formula (I). The present invention was devised on that basis.

An aspect of the present invention relates to an optical recording composition comprising a compound denoted by general formula (I).

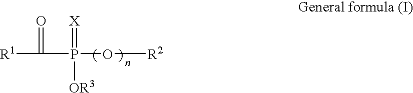

In general formula (I), each of R¹, R², and R³ independently denotes an alkyl group, aryl group, or heterocyclic group, X denotes an oxygen atom or sulfur atom, and n denotes 0 or 1.

In general formula (I), X may denote an oxygen atom.

In general formula (I), R¹ may denote an aryl group in which an alkyl group, aryl group, alkoxy group, or halogen group is present at positions 2 and/or 6.

In general formula (I), n may denote 0 and R² may denote an aryl group.

In general formula (I), n may denote 0 and R³ may denote an alkyl group.

In general formula (I), n may denote 1, and R² and/or R³ may denote an alkyl group.

In general formula (I), R² and R³ may denote an alkyl group.

The above optical recording composition may further comprise a radical polymerizable compound.

The above optical recording composition may further comprise a polyfunctional isocyanate and a polyfunctional alcohol.

The above optical recording composition may be a holographic recording composition.

A further aspect of the present invention relates to a holographic recording medium comprising a recording layer, wherein the recording layer comprises the above-described compound denoted by general formula (I).

The recording layer may further comprise a radical polymerizable compound.

The recording layer may further comprise a polyfunctional isocyanate and a polyfunctional alcohol.

The phosphorus compound denoted by general formula (I) can maintain good recording sensitivity even when incorporated into the recording layer in sufficient quantity for adequate polymerization reaction. Thus, a holographic recording medium can be provided in which the quantity of unreacted monomer remaining after the recording reaction is low, good recording retention capacity is achieved, and high-sensitivity recording is possible. The holographic recording medium of the present invention permits ultrahigh-density recording and is particularly suited as a recording medium for digital volume holography permitting the use of inexpensive lasers and capable of reducing the time required for writing.

Other exemplary embodiments and advantages of the present invention may be ascertained by reviewing the present disclosure and the accompanying drawings.

### BRIEF DESCRIPTION OF THE DRAWINGS

The present invention will be described in the following text by the exemplary, non-limiting embodiments shown in the figures, wherein:

FIG. 1 is a schematic cross-sectional view of an example of a holographic recording medium according to a first implementation embodiment.

FIG. 2 is a schematic cross-sectional view of an example of a holographic recording medium according to a second implementation embodiment.

FIG. 3 is a drawing descriptive of an example of an optical system permitting recording and reproducing of information on a holographic recording medium.

FIG. 4 is a structural diagram of a holographic recording device that can be employed in the present invention.

FIG. 5 is a drawing describing the effective numerical aperture NA.

FIG. 6 is a structural diagram of the holographic recording device of a reflecting type medium.

FIG. 7 is a drawing of an example of the matrix pattern of an informing light and a reference light; (a) shows the case of a high numerical aperture and (b) shows the case of a low numerical aperture.

FIG. 8 is a schematic of the optical system of a planar wave tester.

Explanations of symbols in the drawings are as follows:

1 Lower substrate

2 Reflective film

3 Servo pit pattern

4 Recording layer

5 Upper substrate

6 Filter layer

7 Second gap layer

8 First gap layer

12 Object lens

13 Dichroic mirror

14 Detector

15 ¼ wavelength plate

16 Polarizing plate

17 Half mirror

20 Holographic recording medium

21 Holographic recording medium

22 Holographic recording medium

A Surface through which light enters and exits

10 Holographic recording device

11 Holographic recording device

31 Light source

32 Mirror

33 DMD element

34 Splitter

35 Wavelength plate

36 Object lens

37 Data reading device

39 Base

40 Control device

80 Holographic recording medium

81 Substrate

82 Recording layer

83 Protective layer

IB Informing light

OL Object lens

RB Reference light

F Focal position

### DESCRIPTIONS OF THE EMBODIMENTS

The following preferred specific embodiments are, therefore, to be construed as merely illustrative, and non-limiting to the remainder of the disclosure in any way whatsoever. In this regard, no attempt is made to show structural details of the present invention in more detail than is necessary for fundamental understanding of the present invention; the description taken with the drawings making apparent to those skilled in the art how several forms of the present invention may be embodied in practice.

### Optical Recording Composition

The optical recording composition of the present invention comprises at least a phosphorus compound denoted by general formula (I), can be employed to manufacture a recording material permitting the use of various recording methods of recording information by optical irradiation, is preferably employed as a holographic recording composition, and is particularly suitable as a volume holographic recording composition. As set forth above, holographic recording is a method of recording information by superposing an informing light containing information and a reference light in a recording layer to write an interference image thus formed in the recording layer. Volume holographic recording is a method of recording information in holographic recording in which a three-dimensional interference image is written in the recording layer.

The individual components comprised in the optical recording composition of the present invention will be described below.

### Phosphorus Compound Denoted by General Formula (I)

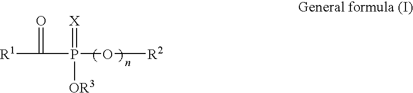

In general formula (I), each of R¹, R², and R³ independently denotes an alkyl group, aryl group, or heterocyclic group.

The alkyl groups denoted by R¹, R², and R³ may be linear or branched, and substituted or unsubstituted. They desirably comprise 1 to 30, preferably 1 to 20, carbon atoms. In the present invention, for a group having one or more substituents, the term “number of carbon atoms” of a group means the number of carbon atoms excluding the substituents.

Examples of these alkyl groups are: methyl groups, ethyl groups, normal propyl groups, isopropyl groups, normal butyl groups, isobutyl groups, tertiary butyl groups, pentyl groups, cyclopentyl groups, hexyl groups, cyclohexyl groups, heptyl groups, octyl groups, tertiary octyl groups, 2-ethylhexyl groups, decyl groups, dodecyl groups, octadecyl groups, 2,3-dibromopropyl groups, adamantyl groups, benzyl groups, and 4-bromobenzyl groups. These may be further substituted. Of these, tertiary butyl groups are greatly preferred from the perspective of stability in the presence of nucleophilic compounds such as water and alcohol.

In general formula (I), the aryl groups denoted by R¹, R², and R³ may be substituted or unsubstituted, and desirably comprise 6 to 30, preferably 6 to 20, carbon atoms. Specific examples of such aryl groups are phenyl groups, naphthyl groups, and anthranyl groups. These may be further substituted. Of these, it is desirable for R¹ to be an aryl group in which an alkyl group, aryl group, alkoxy group, or halogen group is present at least one of positions 2 and 6; preferably an aryl group in which an alkyl group, aryl group, alkoxy group, or halogen group is present at position 2; and more preferably, an aryl group in which an alkyl group, aryl group, alkoxy group, or halogen group is present at both positions 2 and 6. For example, R¹ is desirably a 2-methylphenyl group, 2,4,6-trimethylphenyl group, 2,6-dichlorophenyl group, 2,6-dimethoxyphenyl group, or 2,6-trifluoromethylphenyl group; preferably a 2,4,6-trimethylphenyl group, 2,6-dichlorphenyl group, or 2,6-dimethyoxyphenyl group. It is desirable for the above-described substituent to be present at either position 2 or 6, or both, to enhance stability in the presence of nucleophilic compounds such as water, alcohol, and the like, a description of which may be found in, for example, Jacobi, M.; Henne, A. Polymers Paint Colour Journal 1985, 175, 636, which is expressly incorporated herein by reference in its entirety.

The details of the alkyl group and the aryl group as the above-described substituent are identical to those set forth above.

The alkoxy group as the above-described substituent may be linear or branched, substituted or unsubstituted. It desirably comprises 1 to 30, preferably 1 to 20, carbon atoms. Examples of such alkoxy groups are methoxy groups, ethoxy groups, normal propyloxy groups, isopropyloxy groups, normal butyloxy groups, isobutyloxy groups, tertiary butyloxy groups, pentyloxy groups, cyclopentyloxy groups, hexyloxy groups, cyclohexyloxy groups, heptyloxy groups, octyloxy groups, tertiary octyloxy groups, 2-ethylhexyloxy groups, decyloxy groups, dodecyloxy groups, octadecyloxy groups, 2,3-dibromopropyloxy groups, adamantyloxy groups, benzyloxy groups, and 4-bromobenzyloxy groups. Methyl groups are preferred.

The halogen group as the above-described substituent is desirably a chloro group, bromo group, iodo group, or the like. Bromo groups are preferred.

The heterocyclic groups denoted by R¹, R², and R³ in general formula (I) are desirably four to eight-membered, preferably four to six-membered, and more preferably, five to six-membered. Specific examples are: pyridine rings, piperazine rings, thiophene rings, pyrrole rings, imidazole rings, oxazole rings, and thiazole rings. These may be further substituted. Of the above hetero rings, pyridine rings are preferred.

When the groups denoted by R¹, R², and R³ in general formula (I) are further substituted, examples of the substituents are: halogen groups, alkyl groups, alkenyl groups, alkoxy groups, aryloxy groups, alkylthio groups, alkoxycarbonyl groups, aryloxycarbonyl groups, amino groups, acyl groups, alkylaminocarbonyl groups, arylaminocarbonyl groups, sulfonamide groups, cyano groups, carboxy groups, hydroxyl groups, and sulfonic acid groups. Of these, halogen groups, alkoxy groups, and alkylthio groups are preferred. When R¹ denotes an aryl group as set forth above, the above substituent is desirably present at position 2 and/or position 6 on the aryl group.

In general formula (I), X denotes an oxygen atom or sulfur atom, preferably an oxygen atom.

In general formula (I), n denotes 0 or 1. When n denotes 0, the compound denoted by general formula (I) is denoted by general formula (A) below. When n denotes 1, the compound denoted by general formula (I) is denoted by general formula (B) below.

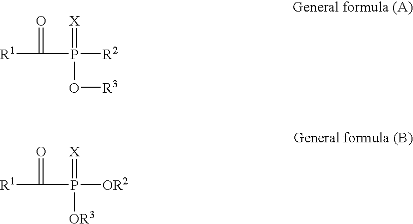

[In general formulas (A) and (B), each of R¹, R², R³, and X is defined as in general formula (I).]

A desirable compound denoted by general formula (A) is a compound in which R¹ denotes an aryl group having an alkyl group, aryl group, alkoxy group, or halogen group at position 2; R¹ denotes an aryl group; R³ denotes an alkyl group; and X denotes an oxygen atom or sulfur atom. A preferred compound is a compound in which R¹ denotes an aryl group having an alkyl group, aryl group, alkoxy group, or halogen group at positions 2 and 6; R¹ denotes an aryl group; R³ denotes an alkyl group; and X denotes an oxygen atom. A compound of greater preference is a compound in which R¹ denotes a 2,6-dimethoxybenzoyl group or 2,6-dichlorobenzoyl group; R² denotes a phenyl group; R³ denotes an ethyl group or isopropyl group; and X denotes an oxygen atom.

Specific examples of phosphorus compounds denoted by general formula (A) are given below. However, the present invention is not limited to the specific examples given below.

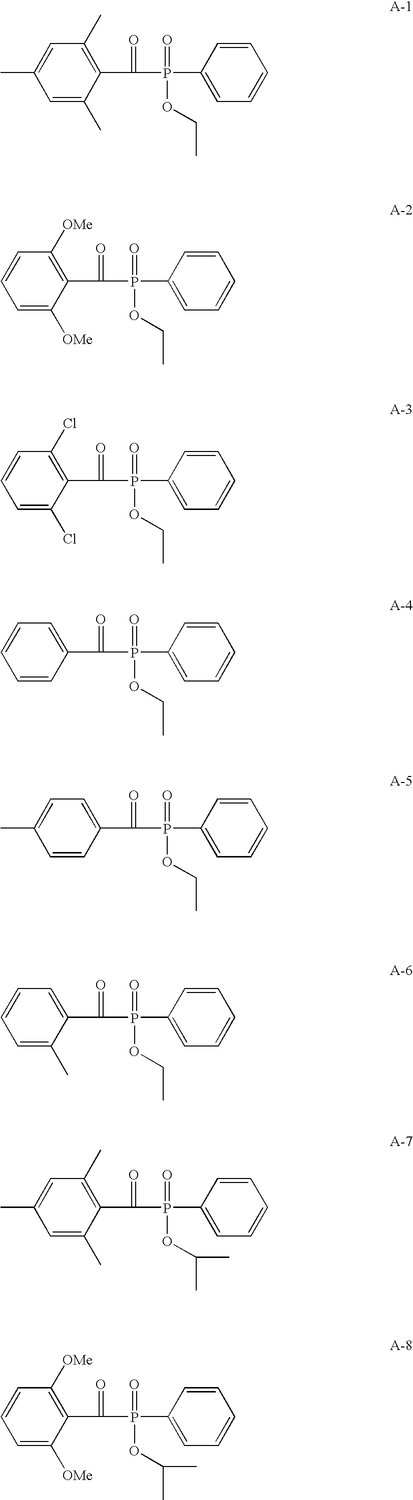

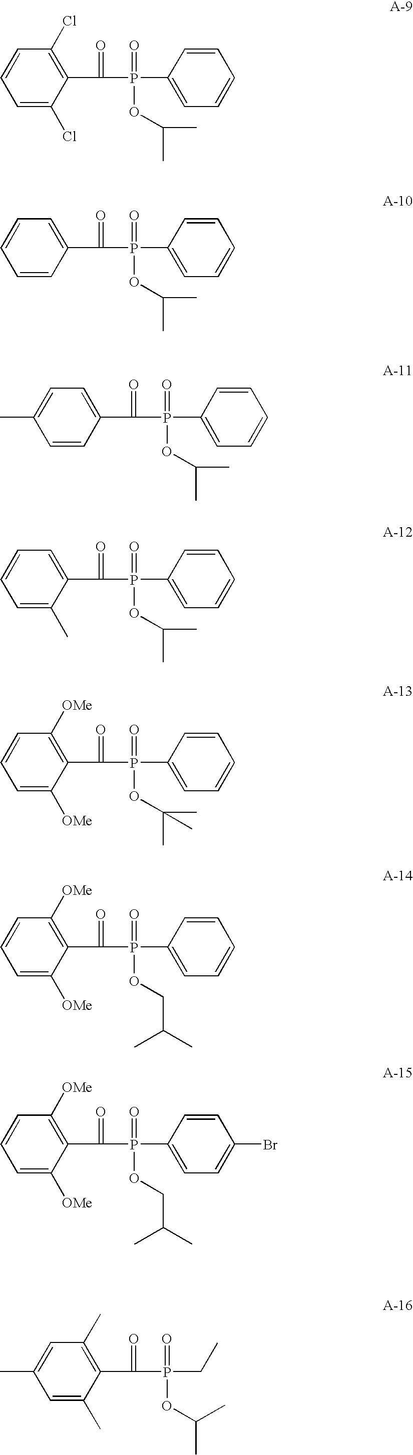

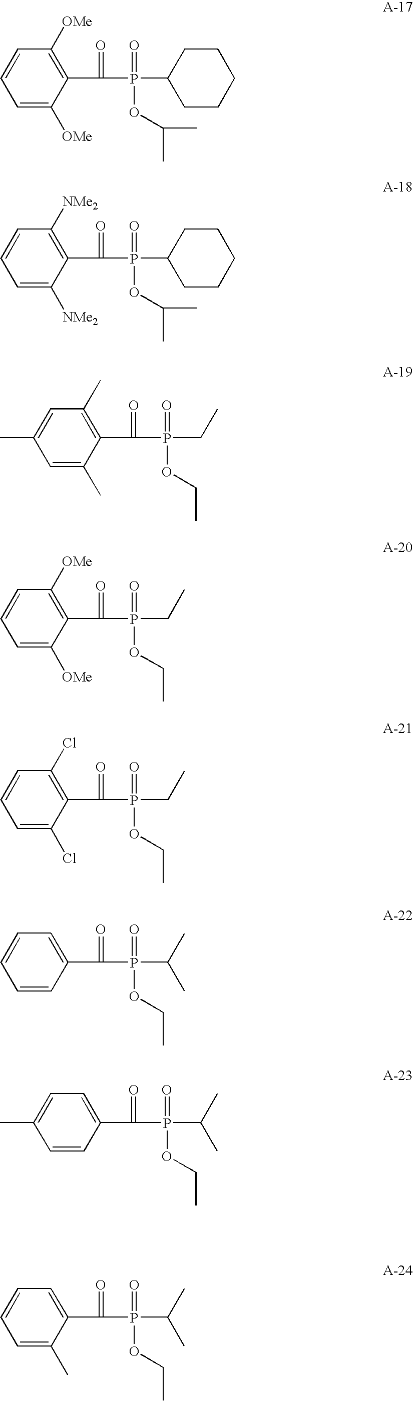

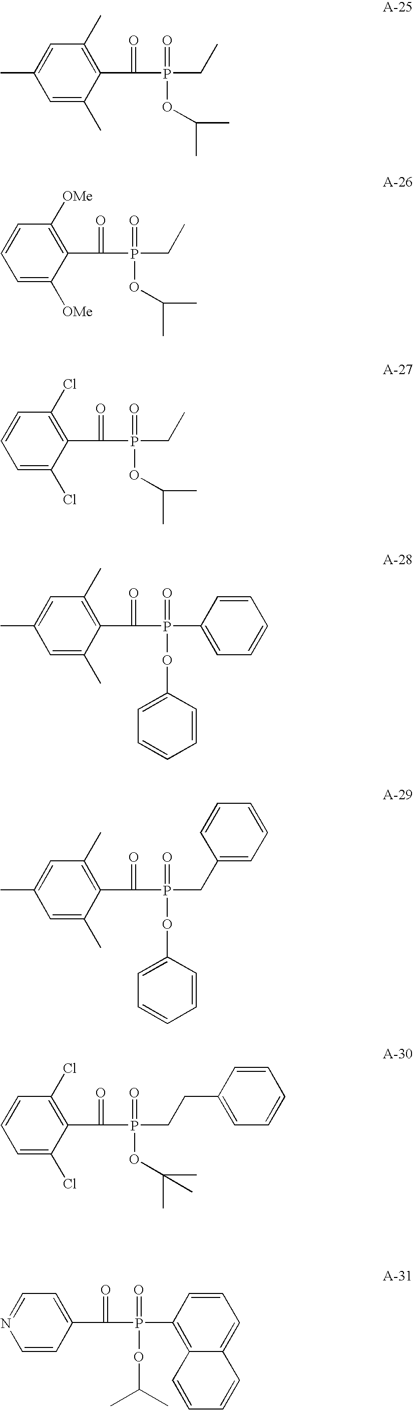

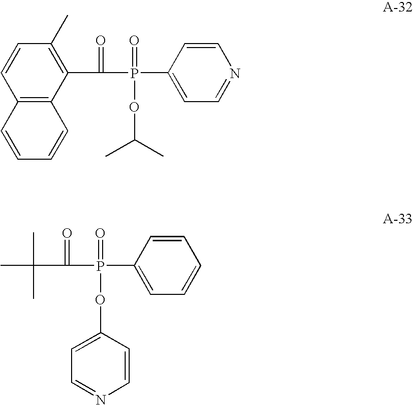

A desirable compound denoted by general formula (B) is a compound in which X denotes an oxygen atom or sulfur atom; R¹ denotes an aryl group having an alkyl group, aryl group, alkoxy group, or halogen group at position 2 and/or position 6; R² denotes an alkyl group; and R³ denotes an alkyl group. A preferred compound is a compound in which X denotes an oxygen atom; R¹ denotes an aryl group having an alkyl group, aryl group, alkoxy group, or halogen group at position 2 and at position 6; R² denotes an alkyl group; and R³ denotes an alkyl group. A compound of greater preference is a compound in which X denotes an oxygen atom; R¹ denotes a 2,6-dimethoxybenzoyl group or 2,6-dichlorobenzoyl group; R² denotes a butyl group or an isopropyl group; and R³ denotes a butyl group or an isopropyl group.

Specific examples of phosphorus compounds denoted by general formula (B) are given below. However, the present invention is not limited to the specific examples given below.

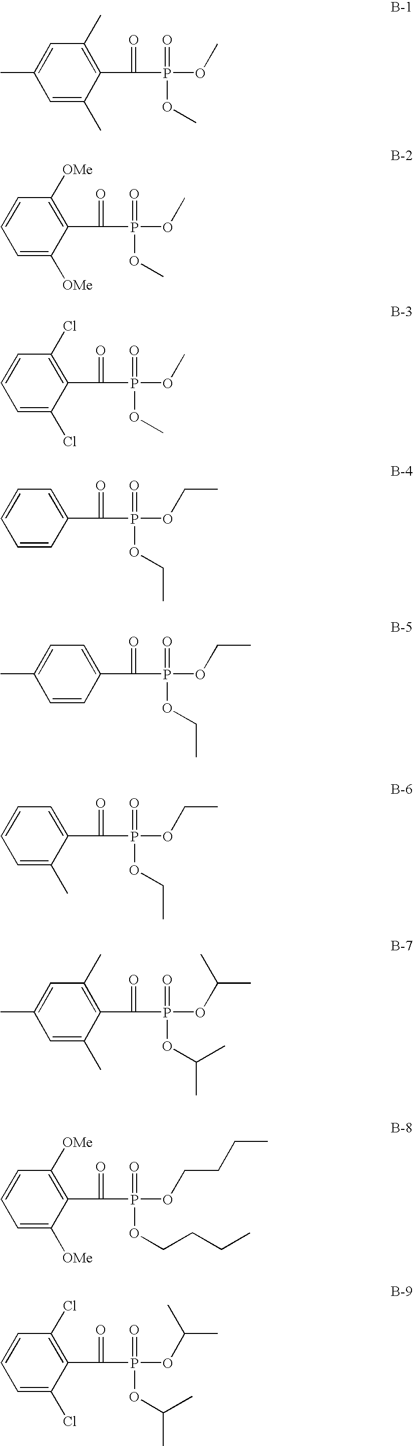

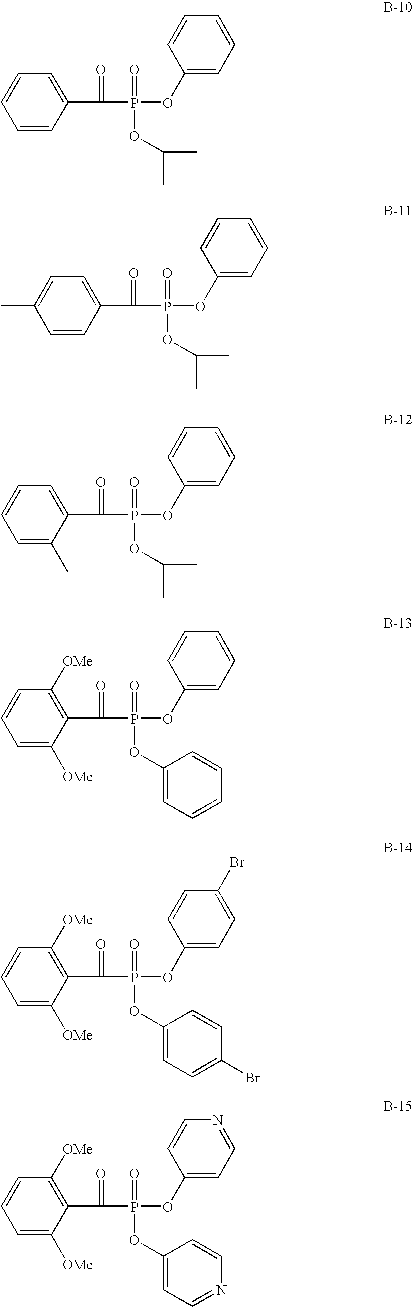

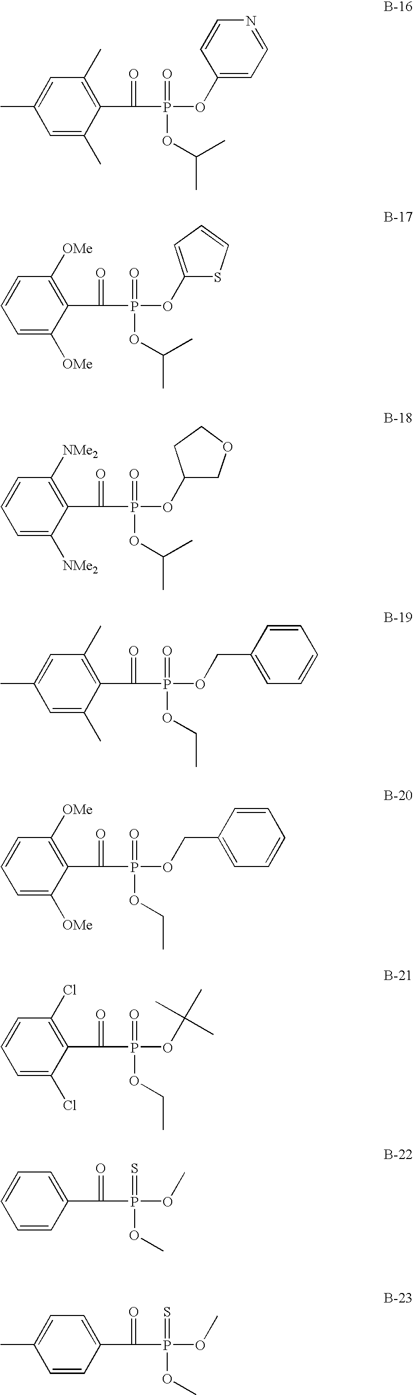

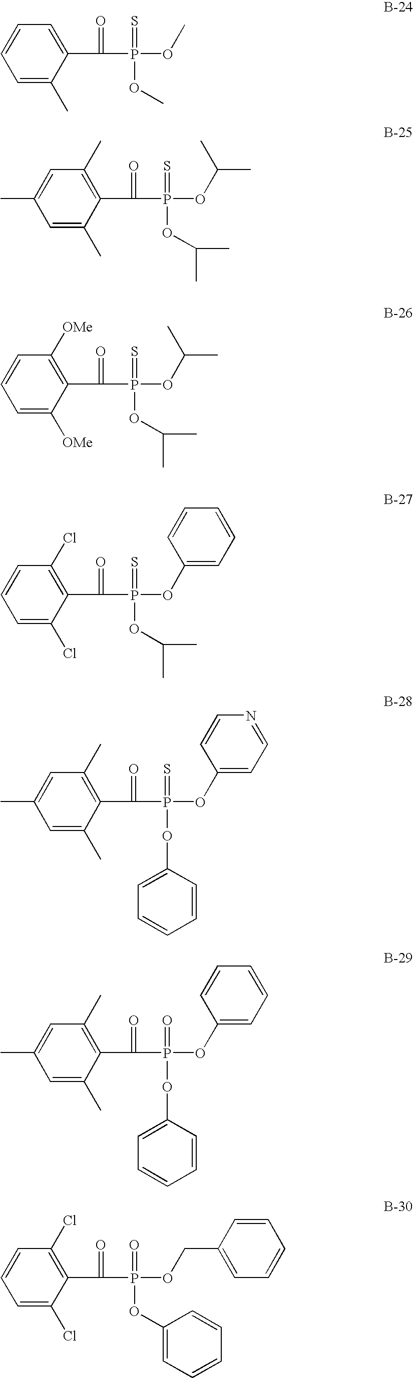

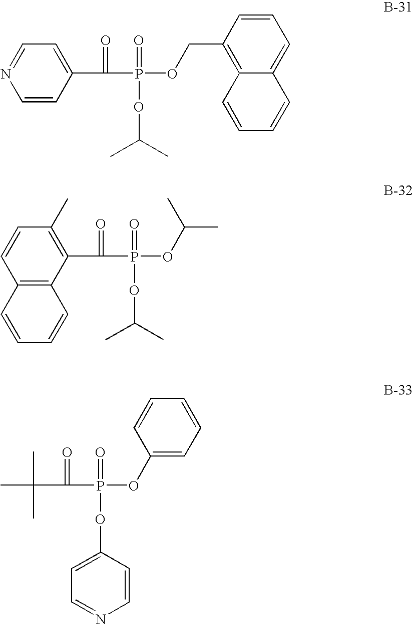

DE2830927A1, U.S. Pat. Nos. 4,292,152, 4,324,744, 4,298,738, 4,385,109 and 4,710,523, for example, describe in detail a method of synthesizing the above-described compounds denoted by general formula (I). The contents of these applications are expressly incorporated herein by reference in their entirety. Examples described further below may also be consulted for synthesis methods.

The optical recording composition of the present invention comprises at least a phosphorus compound denoted by general formula (I). A single phosphorus compound denoted by general formula (I) may be employed, or two or more such compounds may be employed in combination. The content of the phosphorus compound denoted by general formula (I) in the optical recording composition of the present invention is not specifically limited, and may be suitably selected based on the objective. As for the compound denoted by general formula (I) in which n is 0, that is the compound denoted by general formula (A), the content of 0.01 to 5 weight percent is desirable, and 1 to 3 weight percent is preferable. A content of equal to or greater than 0.01 weight percent can ensure interference image with good sensitivity. A content of equal to or less than 5 weight percent permits the formation of a recording layer capable of exhibiting good recording sensitivity with adequate transmittance of the recording light. As for the compound denoted by general formula (I) in which n is 1, that is the compound denoted by general formula (B), the content of 0.01 to 20 weight percent is desirable, and 1 to 10 weight percent is preferable. A content of equal to or greater than 0.01 weight percent can ensure interference image with good sensitivity. A content of equal to or less than 20 weight percent permits the formation of a recording layer capable of exhibiting good recording sensitivity with adequate transmittance of the recording light. The phosphorus compound denoted by general formula (I) can absorb little light at a wavelength of 405 in particular, so when manufacturing a recording medium of identical OD, a larger quantity can be added for use than when employing commercially available short wavelength initiators (such as products sold under the trade names Irg 819 and Darocure TPO (made by Ciba Specialty Chemicals) and products sold under the trade name Lucilin TPO (made by BASF Japan)).

In the optical recording composition of the present invention, the above phosphorus compound can function as a photopolymerization initiator, desirably as a photo-induced radical polymerization initiator. Other photopolymerization initiators can be employed with the phosphorus compound. The photopolymerization initiators that can be employed in combination are not specifically limited other than that they be sensitive to the recording light. From the perspective of the efficiency of the polymerization reaction, photo-induced radical polymerization initiators are desirable. When employing another photopolymerization initiator in combination with the phosphorus compound, the content of the photopolymerization initiator employed with the phosphorus compound in the optical recording composition is desirably equal to or less than 50 weight percent, preferably equal to or less than 30 weight percent, and more preferably, equal to or less than 10 weight percent.

Examples of photo-induced radical polymerization initiators that can be employed in combination are: 2,2′-bis(o-chlorophenyl)-4,4′5,5′-tetraphenyl-1,1′-biimidazole, 2,4,6-tris(trichloromethyl)-1,3,5-triazine, 2,4-bis(trichloromethyl)-6-(p-methoxyphenylvinyl)-1,3,5-triazine, diphenyliodonium tetrafluoroborate, diphenyliodonium hexafluorophosphate, 4,4′-di-t-butyldiphenyliodonium tetrafluoroborate, 4-diethylaminophenyl-benzenediazonium hexafluorophosphate, benzoin, 2-hydroxy-2-methyl-1-phenylpropane-2-one, benzophenone, thioxanthone, 2,4,6-trimethylbenzoyl diphenylacylphosphineoxide, tetraethylammonium triphenylbutyl borate, and bis(η5-2,4-cyclopentadiene-1-yl)bis[2,6-difluoro-3-(1H-pyrrole-1-yl)phenyltitanium]. These can be employed singly or in combinations of two or more. Sensitizing dyes, described further below, can also be combined for use in a manner matching the wavelength of the light being irradiated.

### Polymerizable Compound

The optical recording composition of the present invention may further comprise a recording compound in the form of a polymerizable compound. The polymerizable compound is desirably in the form of a radical polymerizable compound from the perspective of conducting a polymerization reaction that progresses well in combination with the compound denoted in general formula (I). Examples are radical polymerizable monomers having unsaturated bonds, such as acrylic groups, methacrylic groups, styryl groups, and vinyl groups. These polymerizable compounds may be monofunctional or polyfunctional. They may be employed alone, or in combination with two or more other polymerizable compounds.

Examples of radical polymerizable monomers are: acryloyl morpholine, phenoxyethyl acrylate, isobornyl acrylate, 2-hydroxypropyl acrylate, 2-ethylhexyl acrylate, 1,6-hexanediol diacrylate, tripropylene glycol diacrylate, neopentyl glycol PO-modified diacrylate, 1,9-nonanediol diacrylate, hydroxypivalic acid neopentyl glycol diacrylate, EO-modified bisphenol A diacrylate, polyethylene glycol diacrylate, pentaerythritol triacrylate, pentaerythritol tetraacrylate, pentaerythritol hexaacrylate, EO-modified glycerol triacrylate, trimethylol propane triacrylate, EO-modified trimethylol propane triacrylate, 2-naphtho-1-oxyethylacrylate, 2-carbazoyl-9-ylethylacrylate, (trimethylsilyloxy)dimethylsilylpropyl acrylate, vinyl-1-naphthoate, 2,4,6-tribromophenyl acrylate, pentabromoacrylate, phenylthioethyl acrylate, tetrahydrofurfuryl acrylate, bisphenoxyethanolfluorene diacrylate, styrene, p-chlorostyrene, N-vinylcarbazole, and N-vinylpyrrolidone. Of these, phenoxyethyl acrylate, 2,4,6-tribromophenyl acrylate, pentabromoacrylate, and bisphenoxyethanolfluorene diacrylate are desirable, and 2,4,6-tribromophenyl acrylate and bisphenoxyethanolfluorene diacrylate are preferred.

The content of the polymerizable compound in the optical recording composition of the present invention is not specifically limited, and may be suitably selected based on the objective. The content of 1 to 50 weight percent is desirable, 1 to 30 weight percent is preferred, and 3 to 10 weight percent is of greater preference. A content of equal to or lower than 50 weight percent can readily yield a stable interference image. A content of equal to or greater than 1 weight percent can yield desirable properties from the perspective of diffraction efficiency.

### Matrix

The recording layer of an optical recording medium normally comprises a polymer to hold the photopolymerization initiator and monomers related to the recording and storage, known as a matrix. The matrix can be employed for achieving enhanced coating properties, coating strength, and hologram recording characteristics. The optical recording composition of the present invention can comprise curing compounds in the form of a matrix binder and/or matrix forming components (matrix precursors). A method of forming the matrix by, for example, coating a composition containing the matrix precursor on the surface of a substrate and then curing it is desirable because it permits the formation of the recording layer without the use of, or using only a small quantity of, solvent. Thermosetting compounds and light-curing compounds employing catalysts and the like that cure when irradiated with light may be employed as these curing compounds. Thermosetting compounds are desirable from the perspective of recording characteristics.

The thermosetting compound suitable for use in the optical recording composition of the present invention is not specifically limited. The matrix contained in the recording layer may be suitably selected based on the objective. Examples are urethane resins formed from isocyanate compounds and alcohol compounds; epoxy compounds formed from oxysilane compounds; melamine compounds; formalin compounds; ester compounds of unsaturated acids such as (meth)acrylic acid and itaconic acid; and polymers obtained by polymerizing amide compounds.

Of these, polyurethane matrices formed from isocyanate compounds and alcohol compounds are preferable. From the perspective of recording retention properties, three-dimensional polyurethane matrices formed from polyfunctional isocyanates and polyfunctional alcohols are particularly preferred.

The details of polyfunctional isocyanates and polyfunctional alcohols capable of forming polyurethane matrices are described below.

bed below.

Examples of the polyfunctional isocyanates are: biscyclohexylmethane diisocyanate, hexamethylene diisocyanate, phenylene-1,3-diisocyanate, phenylene-1,4-diisocyanate, 1-methoxyphenylene-2,4-diisocyanate, 1-methylphenylene-2,4-diisocyanate, 2,4-tolylene diisocyanate, 2,6-tolylene diisocyanate, 1,3-xylylene diisocyanate, 1,4-xylylene diisocyanate, biphenylene-4,4′-diisocyanate, 3,3′-dimethoxybiphenylene-4,4′-diisocyanate, 3,3′-dimethylbiphenylene-4,4′-diisocyanate, diphenylmethane-2,4′-diisocyanate, diphenylmethane-4,4′-diisocyanate, 3,3′-dimethoxydiphenylmethane-4,4′-diisocyanate, 3,3′-dimethyldiphenylmethane-4,4′-diisocyanate, naphthylene-1,5-diisocyanate, cyclobutylene-1,3-diisocyanate, cyclopentylene-1,3-diisocyanate, cyclohexylene-1,3-diisocyanate, cyclohexylene-1,4-diisocyanate, 1-methylcyclohexylene-2,4-diisocyanate, 1-methylcyclohexylene-2,6-diisocyanate, 1-isocyanate-3,3,5-trimethyl-5-isocyanate methylcyclohexane, cyclohexane-1,3-bis(methylisocyanate), cyclohexane-1,4-bis(methylisocyanate), isophorone diisocyanate, dicyclohexylmethane-2,4′-diisocyanate, dicyclohexylmethane-4,4′-diisocyanate, ethylene diisocyanate, tetramethylene-1,4-diisocyanate, hexamethylene-1,6-diisocyanate, dodecamethylene-1,12-diisocyanate, phenyl-1,3,5-triisocyanate, diphenylmethane-2,4,4′-triisocyanate, diphenylmethane-2,5,4′-triisocyanate, triphenylmethane-2,4′,4″-triisocyanate, triphenylmethane-4,4′,4″-triisocyanate, diphenylmethane-2,4,2′,4′-tetraisocyanate, diphenylmethane-2,5,2′,5′-tetraisocyanate, cyclohexane-1,3,5-triisocyanate, cyclohexane-1,3,5-tris(methylisocyanate), 3,5-dimethylcyclohexane-1,3,5-tris(methylisocyanate), 1,3,5-trimethylcyclohexane-1,3,5-tris(methylisocyanate), dicyclohexylmethane-2,4,2′-triisocyanate, dicyclohexylmethane-2,4,4′-triisocyanate lysine isocyanate methyl ester, and prepolymers having isocyanates on both ends obtained by reacting a stoichiometrically excess quantity of one or more of these organic isocyanate compounds with a polyfunctional active hydrogen-containing compound. Of these, biscyclohexylmethane diisocyanate and hexamethylene diisocyanate are preferred. They may be employed singly or in combinations of two or more.

The polyfunctional alcohols may be in the form of a single polyfunctional alcohol, or in the form of a mixture with two or more polyfunctional alcohols. Examples of these polyfunctional alcohols are: glycols such as ethylene glycol, triethylene glycol, diethylene glycol, polyethylene glycol, propylene glycol, polypropylene glycol, and neopentyl glycol; diols such as butanediol, pentanediol, hexanediol, heptanediol, and tetramethylene glycol; bisphenols; compounds in the form of these polyfunctional alcohols modified by polyethyleneoxy chains or polypropyleneoxy chains; and compounds in the form of these polyfunctional alcohols modified by polyethyleneoxy chains or polypropyleneoxy chains, such as glycerin, trimethylolpropane, butanetriol, pentanetriol, hexanetriol, decanetriol, and other triols.

The content of the above-described matrix-forming components (or matrix) in the optical recording composition of the present invention is desirably 10 to 95 weight percent, preferably 35 to 90 weight percent. When the content is equal to or greater than 10 weight percent, stable interference images can be readily achieved. At equal to or less than 95 weight percent, desirable properties can be obtained from the perspective of diffraction efficiency.

### Other Components

Polymerization inhibitors and oxidation inhibitors may be added to the optical recording composition of the present invention to improve the storage stability of the optical recording composition, as needed.

Examples of polymerization inhibitors and oxidation inhibitors are: hydroquinone, p-benzoquinone, hydroquinone monomethyl ether, 2,6-ditert-butyl-p-cresol, 2,2′-methylenebis(4-methyl-6-tert-butylphenol), triphenylphosphite, trisnonylphenylphoshite, phenothiazine, and N-isopropyl-N′-phenyl-p-phenylenediamine.

The quantity of polymerization inhibitor or oxidation inhibitor added is preferably equal to or less than 3 weight percent of the total quantity of recording monomer. When the quantity added exceeds 3 weight percent, polymerization may slow down, and in extreme cases, ceases.

As needed, a sensitizing dye may be added to the optical recording composition of the present invention. Known compounds such as those described in “Research Disclosure, Vol. 200, 1980, December, Item 20036” and “Sensitizers” (pp. 160-163, Kodansha, ed. by K. Tokumaru and M. Okawara, 1987) and the like may be employed as sensitizing dyes.

Specific examples of sensitizing dyes are: 3-ketocoumarin compounds described in Japanese Unexamined Patent Publication (KOKAI) Showa No. 58-15603; thiopyrilium salt described in Japanese Unexamined Patent Publication (KOKAI) Showa No. 58-40302; naphthothiazole merocyanine compounds described in Japanese Examined Patent Publications (KOKOKU) Showa Nos. 59-28328 and 60-53300; and merocyanine compounds described in Japanese Examined Patent Publications (KOKOKU) Showa Nos. 61-9621 and 62-3842 and Japanese Unexamined Patent Publications (KOKAI) Showa Nos. 59-89303 and 60-60104, which are expressly incorporated herein by reference in their entirety.

Further examples are the dyes described in “The Chemistry of Functional Dyes” (1981, CMC Press, pp. 393-416) and “Coloring Materials” (60 [4] 212-224 (1987)), which are expressly incorporated herein by reference in their entirety. Specific examples are cationic methine dyes, cationic carbonium dyes, cationic quinoneimine dyes, cationic indoline dyes, and cationic styryl dyes.

Further, keto dyes such as coumarin (including ketocoumarin and sulfonocoumarin) dyes, merostyryl dyes, oxonol dyes, and hemioxonol dyes; nonketo dyes such as nonketo polymethine dyes, triarylmethane dyes, xanthene dyes, anthracene dyes, rhodamine dyes, acrylidine dyes, aniline dyes, and azo dyes; nonketo polymethine dyes such as azomethine dyes, cyanine dyes, carbocyanine dyes, dicarbocyanine dyes, tricarbocyanine dyes, hemicyanine dyes, and styryl dyes; and quinone imine dyes such as azine dyes, oxazine dyes, thiazine dyes, quinoline dyes, and thiazole dyes are included among the spectral sensitizing dyes.

These sensitizing dyes may be employed singly or in combinations of two or more.

A photo-heat converting material can be incorporated into the optical recording composition of the present invention for enhancing the sensitivity of the recording layer formed with the optical recording composition.

The photo-heat converting material is not specifically limited, and may be suitably selected based on the functions and properties desired. For example, for convenience during addition to the recording layer with the photopolymer and so as not to scatter incident light, an organic dye or pigment is desirable. From the perspectives of not absorbing and not scattering light from the light source employed in recording, infrared radiation-absorbing dyes are desirable.

Such infrared radiation-absorbing dyes are not specifically limited, and may be suitably selected based on the objective. However, cationic dyes, complex-forming dyes, quinone-based neutral dyes, and the like are suitable. The maximum absorption wavelength of the infrared radiation-absorbing dye preferably falls within a range of 600 to 1,000 nm, more preferably a range of 700 to 900 nm.

The content of infrared radiation-absorbing dye in the optical recording composition of the present invention can be determined based on the absorbance at the wavelength of maximum absorbance in the infrared region in the recording medium formed with the optical recording composition of the present invention. This absorbance preferably falls within a range of 0.1 to 2.5, more preferably a range of 0.2 to 2.0.

As needed, the optical recording composition of the present invention may comprise a component that can diffuse into the inverse direction with that of the polymerizable components in order to reduce the volume change at polymerization, or a compound having an acid cleavage configuration may be added to the holographic recording composition in addition to the polymers.

The optical recording composition of the present invention can be employed as various holographic recording compositions capable of recording information when irradiated with a light containing information. In particular, it is suited to use as a volume holographic recording composition. A recording layer can be formed by coating the optical recording composition of the present invention on a substrate, for example. When the optical recording composition of the present invention contains a thermosetting compound such as those set forth above, a matrix can be formed by promoting the curing reaction by heating following coating. The heating conditions can be determined based on the thermosetting resin employed. The recording layer can be formed by casting when the viscosity of the optical recording composition is adequately low. When the viscosity is so high that casting is difficult, a dispenser can be employed to spread a recording layer on a lower substrate, and an upper substrate pressed onto the recording layer so as to cover it and spread it over the entire surface, thereby forming a recording medium.

### Holographic Recording Medium

The holographic recording medium of the present invention comprises a recording layer comprising the phosphorus compound denoted by general formula (I). The recording layer can be formed with the optical recording composition of the present invention. For example, the recording layer comprised of the optical recording composition of the present invention can be formed by the above-described method.

The recording layer in the holographic recording medium of the present invention comprises a compound denoted by general formula (I). This can increase recording sensitivity and reduce the quantity of unreacted polymerizable compound (residual monomer) following the recording reaction. The content of the compound denoted by general formula (I) in the recording layer is in the same manner as the content in the optical recording composition of the present invention as set forth above.

The holographic recording medium of the present invention comprises the above recording layer (holographic recording layer), and preferably comprises a lower substrate, a filter layer, a holographic recording layer, and an upper substrate. As needed, it may comprise additional layers such as a reflective layer, filter layer, first gap layer, and second gap layer.

The holographic recording medium of the present invention is capable of recording and reproducing information through utilization of the principle of the hologram. This may be a relatively thin planar hologram that records two-dimensional information or the like, or a volumetric hologram that records large quantities of information, such as three-dimensional images. It may be either of the transmitting or reflecting type. Since the holographic recording medium of the present invention is capable of recording high volumes of information, it is suitable for use as a volume holographic recording medium of which high recording density is demanded.

The method of recording a hologram on the holographic recording medium of the present invention is not specifically limited; examples are amplitude holograms, phase holograms, blazed holograms, and complex amplitude holograms. Among these, a preferred method is the so-called “collinear method” in which recording of information in volume holographic recording regions is carried out by irradiating an informing light and a reference light onto a volume holographic recording area as coaxial beams to record information by means of interference pattern through interference of the informing light and the reference light.

Details of substrates and various layers that can be incorporated into the holographic recording medium of the present invention will be described below.

—Substrate—

The substrate is not specifically limited in terms of its shape, structure, size, or the like; these may be suitably selected based on the objective. For example, the substrate may be disk-shaped, card-shaped, or the like. A substrate of a material capable of ensuring the mechanical strength of the holographic recording medium can be suitably selected. When the light employed for recording and reproducing enters after passing through the substrate, a substrate that is adequately transparent at the wavelength region of the light employed is desirable.

Normally, glass, ceramic, resin, or the like is employed as the substrate material. From the perspectives of moldability and cost, resin is particularly suitable. Examples of such resins are: polycarbonate resin, acrylic resin, epoxy resin, polystyrene resin, acrylonitrile—styrene copolymers, polyethylene resin, polypropylene resin, silicone resin, fluorine resin, ABS resin, and urethane resin. Of these, from the perspective of moldability, optical characteristics, and cost, polycarbonate resin and acrylic resin are preferred. Synthesized resins and commercially available resins may both be employed as substrates.

Normally, address servo areas are provided on the substrate at prescribed angular intervals as multiple positioning areas extending linearly in a radial direction, with the fan-shaped intervals between adjacent address servo areas serving as data areas. Information for operating focus servos and tracking servos by the sampled servo method, as well as address information, is recorded (preformatted) as pre-embossed pits (servo pits) or the like in address servo areas. Focus servo operation can be conducted using the reflective surface of a reflective film. Wobble pits, for example, can be employed as information for operating a tracking servo. When the holographic recording medium is card-shaped, it is possible not to have a servo pit pattern.

The thickness of the substrate is not specifically limited, and may be suitably selected based on the objective: a thickness of 0.1 to 5 mm is preferable, with 0.3 to 2 mm being preferred. A substrate thickness of equal to or greater than 0.1 mm is capable of preventing shape deformation during disk storage, while a thickness of equal to or less than 5 mm can avoid an overall disk weight generating an excessive load on the drive motor.

### —Recording Layer—

The recording layer can be formed with the optical recording composition of the present invention and is capable of recording information by holography. The thickness of the recording layer is not specifically limited, and may be suitably selected based on the objective. A recording layer thickness falling within a range of 1 to 1,000 micrometers yields an adequate S/N ratio even when conducting 10 to 300 shift multiplexing, and a thickness falling within a range of 100 to 700 micrometers is advantageous in that it yields a markedly good S/N ratio.

—Reflective Film—

A reflective film can be formed on the servo pit pattern surface of the substrate.

A material having high reflectance for the informing light and reference light is preferably employed as the material of the reflective film. When the wavelength of the light employed as the informing light and reference light ranges from 400 to 780 nm, examples of desirable materials are Al, Al alloys, Ag, and Ag alloys. When the wavelength of the light employed as the informing light and reference light is equal to or greater than 650 nm, examples of desirable materials are Al, Al alloys, Ag, Ag alloys, Au, Cu alloys, and TiN.

By employing an optical recording medium that reflects light as well as can be recorded and/or erased information such as a DVD (digital video disk) as a reflective film, it is possible to record and rewrite directory information, such as the areas in which holograms have been recorded, when rewriting was conducted, and the areas in which errors are present and for which alternate processing has been conducted, without affecting the hologram.

The method of forming the reflective film is not specifically limited and may be suitably selected based on the objective. Various vapor phase growth methods such as vacuum deposition, sputtering, plasma CVD, optical CVD, ion plating, and electron beam vapor deposition may be employed. Of these, sputtering is superior from the perspectives of mass production, film quality, and the like.

The thickness of the reflective film is preferably equal to or greater than 50 nm, more preferably equal to or greater than 100 nm, to obtain adequate reflectance.

—Filter Layer—

A filter layer can be provided on the servo pits of the substrate, on the reflective layer, or on the first gap layer, described further below.

The filter layer has a function of reflecting selective wavelengths in which, among multiple light rays, only light of a specific wavelength is selectively reflected, permitting passing one light and reflecting a second light. It also has a function of preventing generation of noise in which irregular reflection of the informing light and the reference light by the reflective film of the recording medium is prevented without a shift in the selectively reflected wavelength even when the angle of incidence varies. Therefore, by stacking filter layers on the recording medium, it is possible to perform optical recording with high resolution and good diffraction efficiency.

The filter layer is not specifically limited and may be suitably selected based on the objective. For example, the filter layer can be comprised of a laminate in which at least one of a dichroic mirror layer, coloring material-containing layer, dielectric vapor deposition layer, single-layer or two- or more layer cholesteric layer and other layers suitably selected as needed is laminated. The thickness of the filter layer is not specifically limited and may be, for example, about 0.5 to 20 micrometers.

The filter layer may be laminated by direct application on the substrate or the like with the recording layer, or may be laminated on a base material such as a film to prepare a filter layer which is then laminated on the substrate.

### —First Gap Layer—

The first gap layer is formed as needed between the filter layer and the reflective film to flatten the surface of the lower substrate. It is also effective for adjusting the size of the hologram that is formed in the recording layer. That is, since the recording layer should form a certain size of the interference region of the recording-use reference light and the informing light, it is effective to provide a gap between the recording layer and the servo pit pattern.

For example, the first gap layer can be formed by applying a material such as an ultraviolet radiation-curing resin from above the servo pit pattern and curing it. When employing a filter layer formed by application on a transparent base material, the transparent base material can serve as the first gap layer.

The thickness of the first gap layer is not specifically limited, and can be suitably selected based on the objective. A thickness of 1 to 200 micrometers is desirable.

### —Second Gap Layer—

The second gap layer is provided as needed between the recording layer and the filter layer.

The material of the second gap layer is not specifically limited, and may be suitably selected based on the objective. Examples are: transparent resin films such as triacetyl cellulose (TAC), polycarbonate (PC), polyethylene terephthalate (PET), polystyrene (PS), polysulfone (P SF), polyvinylalcohol (PVA), and poly(methyl methacrylate) (PMMA); and norbornene resin films such as a product called ARTON film made by JSR Corporation and a product called Zeonoa made by Japan Zeon Co. Of these, those that are highly isotropic are desirable, with TAC, PC, the product called ARTON, and the product called Zeonoa being preferred.

The thickness of the second gap layer is not specifically limited and may be suitably selected based on the objective. A thickness of 1 to 200 micrometers is desirable.

Specific embodiments of the holographic recording medium of the present invention will be described in greater detail below. However, the present invention is not limited to these specific embodiments.

### First Implementation Embodiment

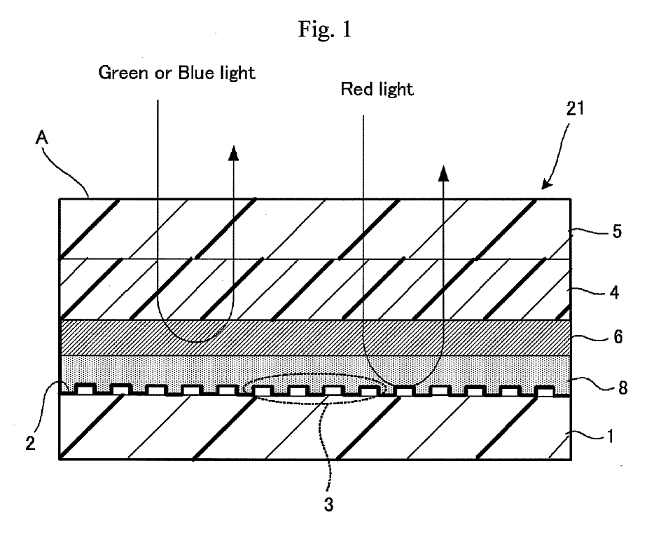

FIG. 1 is a schematic cross-sectional view of the configuration of the holographic recording medium according to the first implementation embodiment. In holographic recording medium 21 according to the first implementation embodiment, a servo pit pattern 3 is formed on substrate 1 made of polycarbonate resin or glass, and aluminum, gold, platinum, or the like is coated on servo pit pattern 3 to provide reflective film 2. In FIG. 1, servo pit pattern 3 has been formed over the entire surface of lower substrate 1, but the servo pit pattern may be formed cyclically. Servo pit pattern 3 is normally 1,750 Angstroms (175 nm) in height, and is quite small relative to the thickness of the substrate and the other layers.

First gap layer 8 is formed by spin coating or the like a material such as an ultraviolet radiation-curing resin on reflective film 2 of lower substrate 1. First gap layer 8 is effective for both the protection of reflective layer 2 and the adjustment of the size of the hologram formed in recording layer 4. That is, providing a gap between recording layer 4 and servo pit pattern 3 is effective for the formation of an interference area for the recording-use reference light and informing light of a certain size in recording layer 4.

Filter layer 6 is provided on first gap layer 8. Recording layer 4 is sandwiched between filter layer 6 and upper substrate 5 (a polycarbonate resin substrate or glass substrate) to form holographic recording medium 21.

FIG. 1 shows a filter layer 6 that passes only infrared radiation and blocks light of all other colors. Accordingly, since the informing light and recording and reproducing-use reference light are blue, they are blocked by filter layer 6 and do not reach reflective film 2. They return, exiting from entry and exit surface A.

Filter layer 6 is a multilayered vapor deposition film comprised of high refractive index layers and low refractive index layers deposited in alternating fashion.

Filter layer 6, comprised of a multilayered vapor deposition film, may be formed directly on first gap layer 8 by vacuum vapor deposition, or a film comprised of a multilayered vapor deposition film formed on a base material may be punched into the shape of a holographic recording medium to employed as filter layer 6.

In this embodiment, holographic recording medium 21 may be disk-shaped or card-shaped. When card-shaped, the servo pit pattern may be absent. In holographic recording medium 21, the lower substrate is 0.6 mm, first gap layer 8 is 100 micrometers, filter layer 6 is 2 to 3 micrometers, recording layer 4 is 0.6 mm, and upper substrate 5 is 0.6 mm in thickness, for a total thickness of about 1.9 mm.

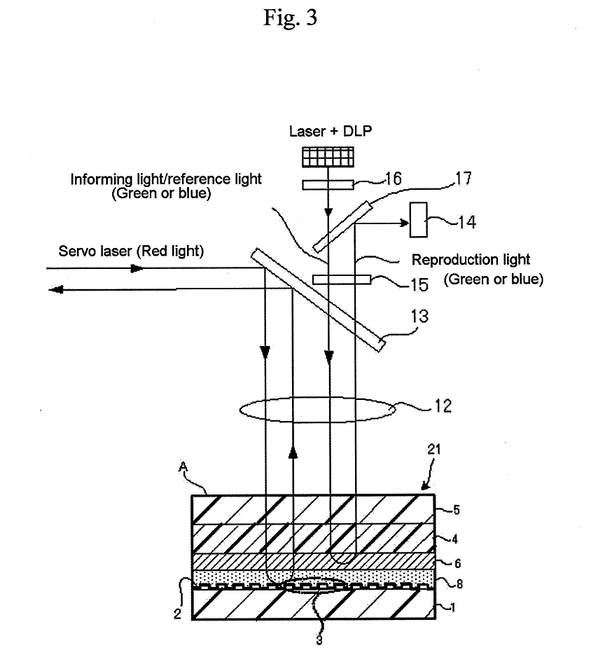

An optical system applicable for the recording of information on and the reproduction of information from holographic recording medium 21 will be described with reference to FIG. 3.

First, a light (red light) emitted by a servo laser is nearly 100 percent reflected by dichroic mirror 13, passing through objective lens 12. Objective lens 12 directs the servo light onto holographic recording medium 21 so that it focuses at a point on reflective film 2. That is, dichroic mirror 13 passes light of green and blue wavelengths while reflecting nearly 100 percent of red light. The servo light entering entry and exit surface A to which and from which the light enters and exits of holographic recording medium 21 passes through upper substrate 5, recording layer 4, filter layer 6, and first gap layer 8, is reflected by reflective layer 2, and passes back through first gap layer 8, filter layer 6, recording layer 4, and upper substrate 5, exiting entry and exit surface A. The returning light that exits passes through objective lens 12, is nearly 100 percent reflected by dichroic mirror 13, and the servo information is detected by a servo information detector (not shown in FIG. 3). The servo information that is detected is employed for focus servo, tracking servo, slide servo, and the like. When the hologram material included in recording layer 4 is not sensitive to red light, the servo light passes through recording layer 4 without affecting recording layer 4, even when the servo light is randomly reflected by reflective film 2. Since the light in the form of the servo light reflected by reflective film 2 is nearly 100 percent reflected by dichroic mirror 13, the servo light is not detected by a CMOS sensor or CCD 14 for reproduction image detection and thus does not constitute noise to the reproduction light.

The informing light and recording-use reference light generated by the recording/reproducing laser passes through polarizing plate 16 and is linearly polarized. It then passes through half mirror 17, becoming circularly polarized light at the point where it passes through ¼ wavelength plate 15. The light then passes through dichroic mirror 13, and is directed by objective lens 12 onto holographic recording medium 21 so that the informing light and recording-use reference light form an interference pattern in recording layer 4. The informing light and recording-use reference light enter through entry and exit surface A, interfering with each other to form an interference pattern in recording layer 4. Subsequently, the informing light and recording-use reference light pass through recording layer 4, entering filter layer 6. However, they are reflected before reaching the bottom surface of filter layer 6, returning. That is, neither the informing light nor the recording-use reference light reaches reflective film 2. That is because filter layer 6 is a multilayered vapor deposition layer in which multiple high refractive index and low refractive index layers are alternatively laminated, and has the property of passing only red light.

### Second Implementation Embodiment

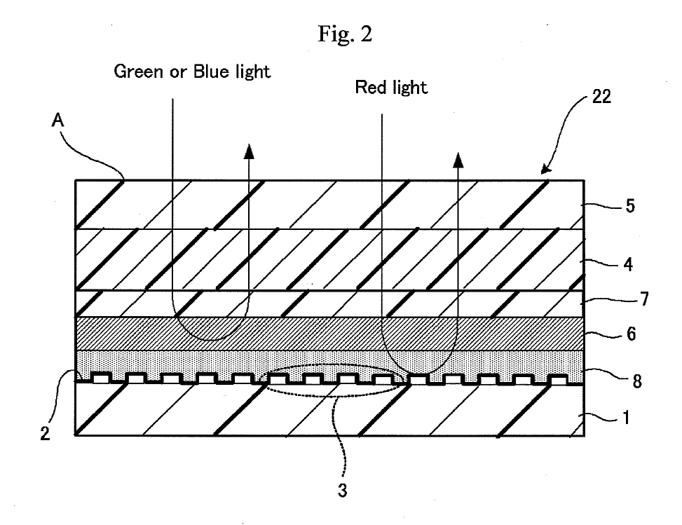

FIG. 2 is a schematic cross-sectional view of the configuration of the holographic recording medium according to the second implementation embodiment. A servo pit pattern 3 is formed on substrate 1 made of polycarbonate resin or glass in the holographic recording medium 22 accoding to the second implementation embodiment. Reflective film 2 is provided by coating aluminum, gold, platinum, or the like on the surface of servo pit pattern 3. Servo pit pattern 3 is normally 1,750 Angstroms (175 nm) in height in the same manner as in the first implementation embodiment.

The configuration of the second implementation embodiment differs from that of the first implementation embodiment in that second gap layer 7 is provided between filter layer 6 and recording layer 4 in holographic recording medium 22 according to the second implementation embodiment. A point at which the informing light and reproduction light are focused is present in second gap layer 7. When this area is embedded in a photopolymer, excessive consumption of monomer occurs due to excess exposure, and multiplexing recording capability diminishes. Accordingly, it is effective to provide a nonreactive transparent second gap layer.

Filter layer 6 in the form of a multilayered vapor deposition film comprised of multiple layers in which multiple high refractive index and low refractive index layers are alternately laminated is formed over first gap layer 8 once first gap layer 8 has been formed, and the same one as employed in the first implementation embodiment can be employed as filter layer 6 in the second implementation embodiment.

In holographic recording medium 22 of the second implementation embodiment, lower substrate 1 is 1.0 mm, first gap 8 is 100 micrometers, filter layer 6 is 3 to 5 micrometers, second gap layer 7 is 70 micrometers, recording layer 4 is 0.6 mm, and upper substrate 5 is 0.4 mm in thickness, for a total thickness of about 2.2 mm.

When recording or reproducing information, a red servo light and a green informing light and recording/reproducing reference light are directed onto holographic recording medium 22 of the second implementation embodiment having the configuration set forth above. The servo light enters through entry and exit surface A, passing through recording layer 4, second gap layer 7, filter layer 6, and first gap layer 8, and is reflected by reflective film 2, returning. The returning light then passes sequentially back through first gap layer 8, filter layer 6, second gap layer 7, recording layer 4, and upper substrate 5, exiting through entry and exit surface A. The returning light that exits is used for focus servo, tracking servo, and the like. When the hologram material included in recording layer 4 is not sensitive to red light, the servo light passes through recording layer 4 and is randomly reflected by reflective film 2 without affecting recording layer 4. The green informing light and the like enters through entry and exit surface A, passing through recording layer 4 and second gap layer 7, and is reflected by filter layer 6, returning. The returning light then passes sequentially back through second gap layer 7, recording layer 4, and upper substrate 5, exiting through entry and exit layer A. During reproduction, as well, the reproduction-use reference light and the reproduction light generated by irradiating the reproduction-use reference light onto recording layer 4 exit through entry and exit surface A without reaching reflective film 2. The optical action around holographic recording medium 22 (objective lens 12, filter layer 6, and detectors in the form of CMOS sensors or CCD 14 in FIG. 3) is identical to that in the first implementation embodiment and thus the description thereof is omitted.

Information can be recorded in the holographic recording medium of the present invention by irradiating the holographic recording medium of the present invention with light. Desirably, when recording information, the recording layer is irradiated with an informing light and a reference light to form an interference image in the recording layer, and the recording layer in which the interference image has been formed is irradiated with a fixing light to fix the interference image. The holographic recording medium of the present invention can yield good recording retention capacity with less residual monomer and exhibit greater recording sensitivity when subjected to the above recording operation and fixing operation.

A light having coherent properties can be employed as the informing light. By irradiating the informing light and reference light onto the recording medium so that the optical axes of the informing light and reference light are coaxial, it is possible to record in the recording layer an interference image generated by interference of the informing light and reference light. Specifically, a informing light imparted with a two dimensional intensity distribution and a reference light of intensity nearly identical to that of the informing light are superposed in the recording layer and the interference pattern that they form is used to generate an optical characteristic distribution in the recording layer, thereby recording information. The wavelengths of the informing light and reference light are preferably equal to or greater than 400 nm, more preferably 400 to 2,000 nm, and further preferably, 400 to 700 nm.

After recording information (forming an interference image) by irradiating the informing light and reference light, a fixing light can be irradiated to fix the interference image. The wavelength of the fixing light is preferably less than 400 nm, more preferably equal to or greater than 100 nm but less than 400 nm, and further preferably, equal to or greater than 200 nm but less than 400 nm.

Information can be reproduced by irradiating a reference light onto an interference image formed by the above-described method. In the course of reading (reproducing) information that has been written, just a reference light is irradiated onto the recording layer with the same arrangement as during recording, causing a reproduction light having an intensity distribution corresponding to the optical characteristic distribution formed in the recording layer to exit the recording layer.

An optical recording and reproduction device that is suitably employed to record and reproduce information on the holographic recording medium of the present invention will be described below with reference to the figures.

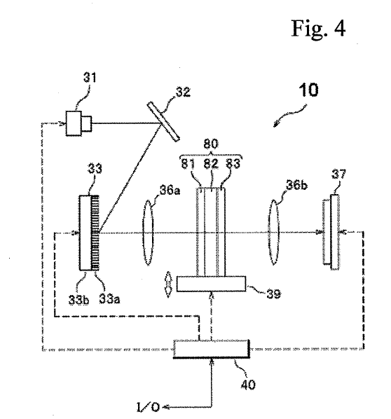

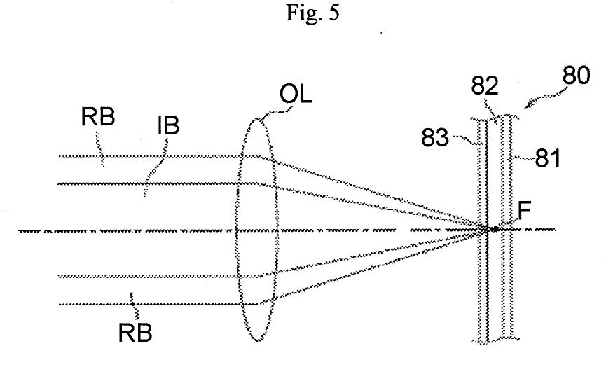

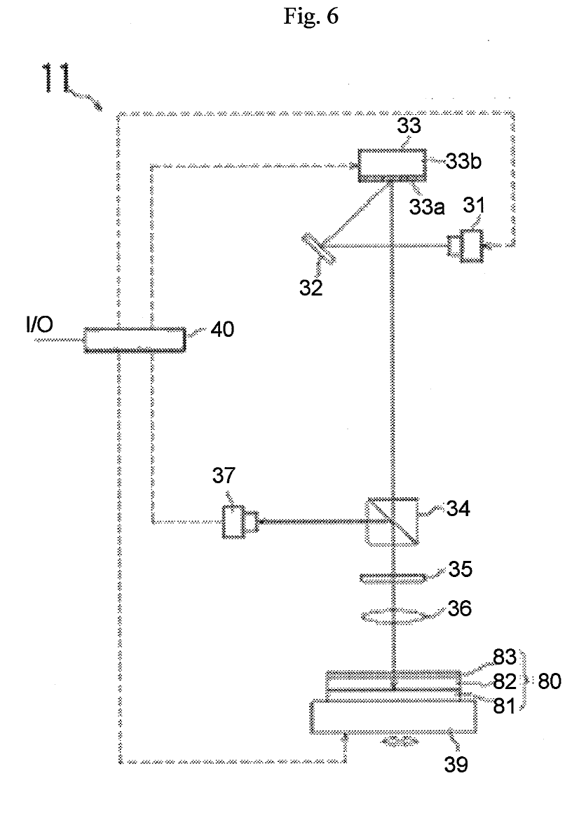

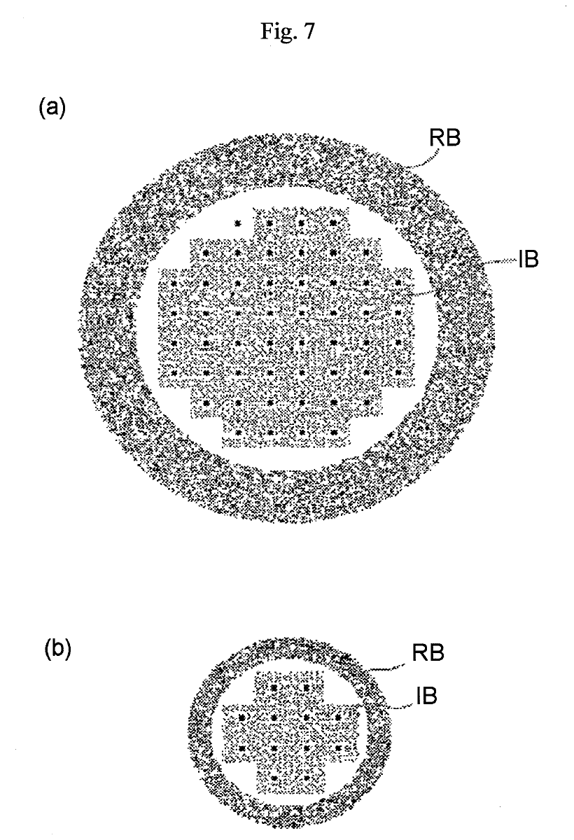

FIG. 4 is a structural diagram of a holographic recording device that can be employed in the present invention. FIG. 5 is a drawing describing the effective numerical aperture NA. FIG. 6 is a structural diagram of a holographic recording device that can be used to record and reproduce information on a reflecting type medium. FIG. 7 is a drawing of an example of the matrix pattern of an informing light and a reference light: (a) shows the case of a high numerical aperture and (b) shows that of a low numerical aperture.

The recording and reproduction of information will be described next based on FIGS. 4 to 7.

The holographic recording device 10 shown in FIG. 4 is primarily comprised of a light source 31, mirror 32, DMD element 33, object lenses 36a and 36b, data reading device 37, base 39, and control device 40.

Light source 31 emits a coherent light, and is disposed so that the light is emitted toward mirror 32.

Mirror 32 is disposed so that the light from light source 31 reflects toward DMD element 33.

DMD element 33 is comprised of multiple minute mirrors 39a disposed in a matrix configuration, and a switching device 33b that switches the orientation of individual mirrors 33a. Light arriving from the mirror 32 side is reflected off prescribed mirrors 39a to generate an informing light IB and a reference light RB. For example, a portion of multiple mirrors 39a disposed in a ring-shaped region near the perimeter are oriented toward object lens 36a in a prescribed pattern, and a ring-shaped light reflecting off this portion of mirrors 39a is employed as reference light RB (see FIGS. 7(a) and (b)). The orientation of multiple mirrors 39a arranged to the inside of the portion of mirrors 39a forming reference light RB can be suitably adjusted to the orientation of the object lens 36a side and some other orientation based on data inputted through control device 40, and the light reflected by the mirrors 39a of this inner region employed as informing light IB (see FIGS. 7(a) and (b)). That is, DMD element 33 causes optical information to be disposed in matrix form in the cross section of informing light IB.

Object lens 36a focuses reference light RB and informing light IB arriving from DMD element 33, causing them to interfere in recording layer 82 of recording medium 80. Object lens 36a, base 39, and recording medium are arranged so that the optical axes of the lights focused by object lens 36a are perpendicular to recording layer 82 (perpendicular to the planar direction, running in the direction of thickness).

Data reading device 37 allocates a reading light equal to reference light RB to the interference fringe recorded in recording layer 82, and reads as data the light that is diffracted by the interference fringe and passes through object lens 36b. Specifically, the light that enters data reading device 37 contains the same optical information in matrix form as that contained by informing light IB during recording. Thus, this optical information in matrix form can be read using CMOS, CCD, or the like.

Base 39 is configured to support recording medium and to be capable of displacement relative to the light so as to change the recording position in recording medium by moving in a direction orthogonal to the optical axis of the light entering recording medium 80, thereby permitting recording of information over the entire surface of recording medium 80. For example, base 39 can be configured as a rotating stage. Specifically, although not shown, it is also possible to displace object lens 36 relative to base 39.

Control device 40 digitally controls light source 31, DMD element 33, and base 39.

Control device 40 is connected to a device that provides instructions for recording information to holographic recording device 10, such as a personal computer terminal, image recording device, or the like. Information from such a device is inputted in the course of recording information, and information that has been read is outputted to this device in the course of reading information.

When recording information, control device 40 changes the orientation of mirrors 39a of DMD element 33 based on the information being recorded, emits light from light source 31, and generates informing light IB and reference light RB. It also drives base 39 to record recording spots (interference fringes) at suitable positions on recording medium 80.

Control device 40 is configured so that when reading information from recording medium 80, it controls the mirrors 39a in the region corresponding to the informing light IB of DMD element 33 so that the light is not oriented toward object lens 36a and controls the mirrors 39a in the region corresponding to the reference light RB so that they are oriented in the same pattern as during recording, thereby irradiating only reference light RB into recording medium 80. It drives base 39 so that the recording spots to be read (interference fringes) on recording medium are irradiated by reference light RB. It also picks up informing light IB entering data reading device 37 and outputs it to the device that has provided reading instructions.

In the present embodiment, no reflective layer is present on recording medium 80, which is a transmitting type holographic recording medium 80. For example, when recording and reproducing information in a reflecting type holographic recording medium in which a reflective layer is present between substrate 81 and recording layer 82, recording and reproduction can be conducted based on the configuration indicated by holographic recording device 11 as shown in FIG. 6, in which a deflecting light splitter 34 and a ¼ wavelength plate 35 have been added to holographic recording device 10. Recording and reproduction with the recording device shown in FIG. 6 will be described below.

Holographic recording device 11 shown in FIG. 6 is primarily comprised of a light source 31, mirror 32, DMD element 33, splitter 34, wavelength plate 35, object lens 36, data reading device 37, base 39, and control device 40.

Light source 31 emits a coherent light, and is disposed so that the light is emitted toward mirror 32.

Mirror 32 is disposed so that the light from light source 31 reflects toward DMD element 33.

DMD element 33 is comprised of multiple minute mirrors 39a disposed in a matrix configuration, and a switching device 33b that switches the orientation of individual mirrors 33a. Light arriving from the mirror 32 side is reflected off prescribed mirrors 39a to generate an informing light IB and a reference light RB. For example, a portion of multiple mirrors 39a disposed in a ring-shaped region near the perimeter are oriented toward splitter 34 in a prescribed pattern, and a ring-shaped light reflecting off this portion of mirrors 39a is employed as reference light RB (see FIGS. 7(a) and (b)). The orientation of multiple mirrors 39a arranged to the inside of the portion of mirrors 39a forming reference light RB can be suitably adjusted to the orientation of the splitter 34 side and some other orientation based on data inputted through control device 40, and the light reflected by the mirrors 39a of this inner region employed as informing light IB (see FIGS. 7(a) and (b)). That is, DMD element 33 causes optical information to be disposed in matrix form in the cross section of informing light IB.

Splitter 34 causes the light arriving from the DMD element 33 side to pass through to the wavelength plate 35 side and causes the light arriving from the wavelength plate 35 side to reflect to the data reading device 37 side.

Wavelength plate 35 is a ¼ wavelength plate having the functions of converting a linear deflection to a circular deflection and converting a circular deflection to a linear deflection.

Object lens 36a focuses reference light RB and informing light IB arriving from DMD element 33 via splitter 34 and wavelength plate 35, causing them to interfere in recording layer 82 of recording medium 80. Object lens 36, base 39, and recording medium are arranged so that the optical axes of the lights focused by object lens 36 are perpendicular to recording layer 82 (perpendicular to the planar direction, running in the direction of thickness).

Data reading device 37 allocates a reading light equal to reference light RB to the interference fringe recorded in recording layer 82, and reads as data the light from the interference fringe side that sequentially passes through and is reflected by object lens 36, wavelength plate 35, and splitter 34. Specifically, the beam that enters data reading device 37 contains the same optical information in matrix form as that contained by informing light IB during recording. Thus, this optical information in matrix form can be read using CMOS, CCD, or the like.

Base 39 is configured to support recording medium and to be capable of displacement relative to the light so as to change the recording position in recording medium by moving in a direction orthogonal to the optical axis of the light entering recording medium 80, thereby permitting recording of information over the entire surface of recording medium 80. For example, base 39 can be configured as a rotating stage. Specifically, although not shown, it is also possible to displace object lens 36 relative to base 39.

Control device 40 digitally controls light source 31, DMD element 33, and base 39.

In the embodiments shown in FIGS. 4 and 6, control device 40 is connected to a device that provides instructions for recording information to holographic recording device 10, such as a personal computer terminal, image recording device, or the like. Information from such a device is inputted in the course of recording information, and information that has been read is outputted to this device in the course of reading information.

When recording information, control device 40 changes the orientation of mirrors 39a of DMD element 33 based on the information being recorded, emits light from light source 31, and generates informing light IB and reference light RB. It also drives base 39 to record recording spots (interference fringes) at suitable positions on recording medium 80.

Control device 40 is configured so that when reading information from recording medium 80, it controls the mirrors 39a in the region corresponding to the informing light IB of DMD element 33 so that the light is not oriented toward object lens 36a and controls the mirrors 39a in the region corresponding to the reference light RB so that they are oriented in the same pattern as during recording, thereby irradiating only reference light RB into recording medium 80. It drives base 39 so that the recording spots to be read (interference fringes) on recording medium are irradiated by reference light RB. It also picks up informing light IB entering data reading device 37 and outputs it to the device that has provided reading instructions.

Specific embodiments of a holographic recording device that can be employed in the present invention have been described above. However, the present invention is not limited to the above-described embodiments, and can be suitably modified. For example, multiple recording spots denoting different information can be recorded in overlapping fashion by a known multiplexing method such as the shift multiplexing method, code multiplexing method, or phase-code multiplexing method to record more information. Further, the configuration of recording medium is not limited to that exemplified above; a separate layer, such as a servo layer, can be present.

### EXAMPLES

The present invention will be described in detail below based on examples. However, the present invention is not limited to the examples.

### <Synthesis Examples of Compounds Denoted by General Formula (A)>

Example compounds A-2, A-3, A-8, and A-9 were synthesized by the general scheme set forth below in accordance with the method described in DE2830927A1. In the scheme set forth below, R¹ to R³ are defined as in general formula (I). Various compounds in which R¹ to R³ differ can be synthesized with various synthesis starting materials by the scheme set forth below.

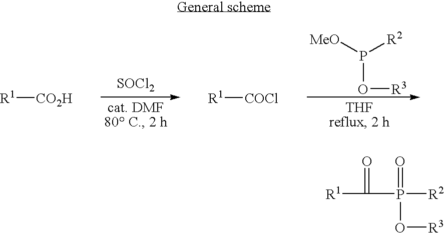

Identification results of Example compounds A-2, A-3, A-8, and A-9 thus obtained are given below.

<A-2>

¹H NMR (300 MHz, CDCl₃) δ 1.32 (t, 3H), 3.62(s, 6H), 4.13-4.26 (m, 2H), 6.4 9 (d, 2H), 7.32(t, 1H), 7.40-7.51 (m, 2H), 7.54-7.59(m, 1H), 7.79 (dd, 2H)

<A-3>

¹H NMR (300 MHz, CDCl₃) δ 1.37 (d, 3H), 1.39 (d, 3H), 4.91-4.98 (m, 1H) 7. 29 (s, 3H), 7.47-7.51 (m, 2H), 7.59-7.61 (m, 1H), 7.91 (dd, 2H)

<A-8>

¹H NMR (300 MHz, CDCl₃) δ 1.34 (d, 3H), 1.38 (d, 3H), 3.67(s, 6H), 4.68-4.8 0 (m, 1H), 7.32 (t, 1H), 7.41-7.50 (m, 2H), 7.52-7.59 (m, 1H), 7.90 (dd, 2H)

<A-9>

¹H NMR (300 MHz, CDCl₃) δ 1.36 (t, 3H), 4.41 (q, 2H), 7.28 (s, 3H), 7.58-7.6 4 (m, 1H), 7.93 (dd, 2H)

Example compounds B-2, B-3, B-8, and B-9 were synthesized by the general scheme set forth below in accordance with the method described in DE2830927A1. In the scheme set forth below, R¹ to R³ are defined as in general formula (I). Various compounds in which R¹ to R³ differ can be synthesized with various synthesis starting materials by the scheme set forth below.

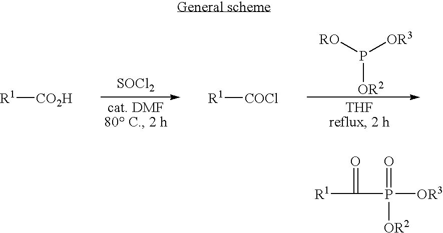

As specific examples, synthesis schemes and identification results of Example compounds B-8 and B-9 are given below.

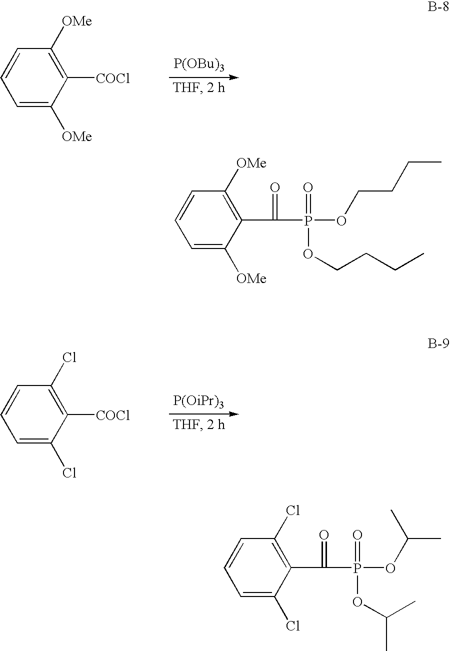

<B-8>

¹H NMR (300 MHz, CDCl₃) δ 0.91 (t, 6H), 1.38 (dd, 4H), 1.64(dd, 4H), 3.82 (s, 6H), 4.08-4.19 (m, 4H), 6.59 (d, 2H), 7.38 (t, 1H)

<B-9>

¹H NMR (300 MHz, CDCl₃) δ 1.32 (d, 6H), 1.39 (d, 6H), 4.82-4.94 (m, 2H), 7.33 (s, 3H)

### Example 1

### Preparation of Holographic Recording Composition

A 6.4 g quantity of hexamethylene diisocyanate (made by Mitsui Chemicals Polyurethanes, Inc.; trade name: Takenate T-700), 5.21 g of polypropylene oxide triol (made by Mitsui Chemicals Polyurethanes, Inc.; trade name: MN-300), 4.64 g of polyethylene glycol (made by Tokyo Chemical Industry Co., Ltd.), 1.85 g of 9,9′-biphenylfluorene EO-modified acrylate (made by Osaka Gas Chemicals (Ltd.), trade name: Ogsol EA0200), 0.16 g of Example Compound A-2, and 0.20 g of amine curing catalyst (made by SAN-APRO; trade name: U-CAT 410) were mixed under a nitrogen gas flow to prepare a holographic recording composition.

### Example 2

### Preparation of Holographic Recording Composition

With the exception that Example Compound A-3 was employed instead of Example Compound A-2 in Example 1, a holographic recording composition was prepared in the same manner as in Example 1.

### Example 3

### Preparation of Holographic Recording Composition

With the exception that Example Compound A-8 was employed instead of Example Compound A-2 in Example 1, a holographic recording composition was prepared in the same manner as in Example 1.

### Example 4

### Preparation of Holographic Recording Composition

With the exception that Example Compound A-9 was employed instead of Example Compound 1-2 in Example 1, a holographic recording composition was prepared in the same manner as in Example 1.

### Example 5

### Preparation of Holographic Recording Composition

A 6.4 g quantity of hexamethylene diisocyanate (made by Mitsui Chemicals Polyurethanes, Inc.; trade name: Takenate T-700), 5.21 g of polypropylene oxide triol (made by Mitsui Chemicals Polyurethanes, Inc.; trade name: MN-300), 4.64 g of polyethylene glycol (made by Tokyo Chemical Industry Co., Ltd.), 1.85 g of 9,9′-biphenylfluorene EO-modified acrylate (made by Osaka Gas Chemicals (Ltd.), trade name: Ogsol EA0200), 1.60 g of Example Compound B-8, and 0.20 g of amine curing catalyst (made by SAN-APRO; trade name: U-CAT 410) were mixed under a nitrogen gas flow to prepare a holographic recording composition.

### Example 6

### Preparation of Holographic Recording Composition

With the exception that Example Compound B-3 was employed instead of Exemplary Compound B-8 in Example 5, a holographic recording composition was prepared in the same manner as in Example 5.

### Comparative Example 1

### Preparation of Holographic Recording Composition

A 6.4 g quantity of hexamethylene diisocyanate (made by Mitsui Chemicals Polyurethanes, Inc.; trade name: Takenate T-700), 5.21 g of polypropylene oxide triol (made by Mitsui Chemicals Polyurethanes, Inc.; trade name: MN-300), 4.64 g of polyethylene glycol (made by Tokyo Chemical Industry Co., Ltd.), 1.85 g of 9,9′-biphenylfluorene EO-modified acrylate (made by Osaka Gas Chemicals (Ltd.), trade name: Ogsol EA0200), 0.16 g of photopolymerization initiator (2,4,6-trimethylbenzoylphenylphosphinic acid ethyl ester; trade name: Lucirin TPO-L, made by BASF Japan), and 0.20 g of amine curing catalyst (made by SAN-APRO; trade name: U-CAT 410) were mixed under a nitrogen flow to prepare a holographic recording composition.

### Comparative Example 2

### Preparation of Holographic Recording Composition

A 3.85 g quantity of Baytec WE-180 isocyanate (made by Bayer), 5.63 g of polypropylene oxide triol (made by Mitsui Chemicals Polyurethanes, Inc.; trade name: MN-1000), 0.35 g of 2,4,6-tribromophenyl acrylate, 0.08 g of photopolymerization initiator (Irg-819 made by Ciba Specialty Chemicals), and 0.09 g of tin curing catalyst dibutyl tin dilaurate (made by Tokyo Chemical Industry Co., Ltd.) were mixed under a nitrogen flow to prepare a holographic recording composition.

### Examples 7 to 12, Comparative Examples 3 and 4

### Preparation of Optical Recording Medium

A first substrate was prepared by subjecting one side of a glass sheet 0.5 mm in thickness to an antireflective treatment to impart a reflectance of 0.1 percent for perpendicularly incident light with the wavelength of 405 nm.

A second substrate was prepared by subjecting one side of a glass sheet 0.5 mm in thickness to an aluminum vapor deposition treatment to impart a reflectance of 90 percent for perpendicularly incident light with the wavelength of 405 nm.

A transparent polyethylene terephthalate sheet 500 micrometers in thickness was provided as a spacer on the side of the first substrate that had not been subjected to the antireflective treatment.

The holographic recording compositions of Examples 1 to 6 and Comparative Examples 1 and 2 were each separately placed on first substrates, the aluminum vapor deposited surface of the second substrates were stacked on the holographic recording composition in such a manner that air was not entrained, and the first and second substrates were bonded through the spacer. Subsequently, Examples 7 to 12 and Comparative Examples 3 and 4 were left for 6 hours at 80° C. to prepare various optical recording media (holographic recording media). The thickness of the recording layers formed was 200 micrometers in all media prepared.

### <Recording in the Optical Recording Medium and Evaluation>

(1)Measurement of Recording Sensitivity by Digital Tester

Holograms were written at a recording spot with a diameter of 200 micrometers at the focal position of the recording hologram in the optical recording media of Examples 7 to 12 and Comparative Example 3 and 4 using the above-described hologram recording and reproduction tester, shown in FIG. 4. Next, fixing was conducted so that absorption of the recording light source was almost nil in the samples (fixing light source: UV-LED (UV-300) made by Keyence, wavelength: 300 nm). Subsequently, as set forth below, the sensitivity (recording energy) was evaluated. The wavelength of the informing light and reference light employed in recording and the wavelength of the reproduction light were 405 nm.

—Sensitivity Measurement —

The beam energy during recording (mJ/cm²) was varied and the change in the error rate (BER: bit error rate) of the reproduced signal was measured. Normally, there is such a tendency that the luminance of the reproduced signal increases and the BER of the reproduced signal gradually drops with an increase in the irradiated light energy. In the measurement, the lowest light energy at which a fairly good reproduced image (BER <10⁻³) was obtained was adopted as the recording sensitivity of the optical recording medium. Results are given in Table 1.

(2) Measurement of Recording Capacity by Planar Wave Tester

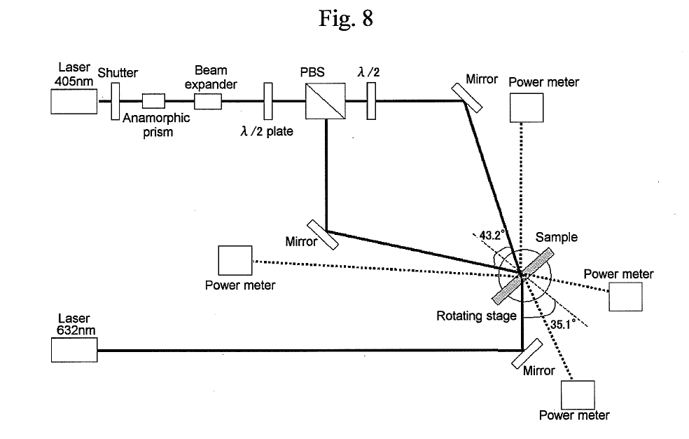

FIG. 8 shows a schematic of the optical system of a planar wave recording tester. A “Littrow” blue laser made by SONY (wavelength: 405 nm) was employed as the recording light source and an He—Ne laser (wavelength: 633 nm) that was not absorbed by the medium was employed as the probe light source. The luminous energy of the recording light source was 4 [mW] with the informing light and reference light combined. The luminous energy of the probe light source was 5 [mW]. The crossing angle of the informing light and the reference light was 43.2° (grating interval: 550 nm). The angle of incidence of the probe light—the angle at which the Bragg condition was satisfied—was 35.10°. A recording spot diameter of 6 mm was employed. The dynamic range of the storage capacity is denoted by an index referred to as “M#”. The recording capacity of each of the optical recording media of Example 7 and 12 and Comparative Examples 3 and 4 was measured with the above-described optical system. The measurement is described below.

Adopting a diffraction efficiency of 1 to 3 percent per cycle as standard, in a manner not exceeding 10 percent, 61 multiplexed recordings were conducted at intervals of 1° from −30° to +30° until the sensitivity of the recording material almost disappeared. Fixing was conducted until absorption of the recording light source by the sample almost ceased (fixing light source: High-power UV-LED (UV-400) made by Keyence), the angular selectivity was evaluated at 0.01° intervals from −32° to +32°, and the square roots of the diffraction efficiencies ηᵢ of the peaks obtained were summed to calculate M#. Diffraction efficiency η was evaluated as set forth below. The results are given in Table 1.

η=diffracted light/(diffracted light+transmitted light)×100

M#=Σ√ηᵢ

(3) Measurement of Quantity of Residual Monomer

The entire surface of each of the optical recording media manufactured as set forth above was irradiated with 20,000 mJ/cm² of light with a wavelength of 405 nm and the residual monomer was extracted from the recording medium. The quantity of monomer extracted was determined by liquid chromatography using a calibration curve. The results are given in Table 1.

TABLE 1

| | | Digital tester | | Quantity of |
|---|---|---|---|---|
| | Holographic | Recording | Planar wave | residual |
| | recording | sensitivity | tester | monomer |
| | composition | (mJ/cm²) | M# | % |
| Example 7 | Example 1 | 43 | 9.8 | 13.5 |
| Example 8 | Example 2 | 54 | 11.0 | 8.5 |
| Example 9 | Example 3 | 45 | 11.0 | 8.6 |
| Example 10 | Example 4 | 56 | 10.0 | 11.2 |
| Example 11 | Example 5 | 49 | 13.2 | 7.3 |
| Example 12 | Example 6 | 52 | 14.6 | 6.9 |
| Comp. Ex. 3 | Comp. Ex. 1 | 80 | 9.0 | 50.3 |
| Comp. Ex. 4 | Comp. Ex. 2 | 60 | 5.8 | 68.0 |

Table 1 reveals that the optical recording media of Examples 7 to 12, in which the holographic recording compositions of Examples 1 to 6 were employed, all exhibited better recording sensitivity, better multiplexed recording characteristics, and less residual monomer than the optical recording media of Comparative Examples 3 and 4, in which the holographic recording compositions of Comparative Examples 1 and 2 were employed.

The optical recording composition of the present invention is capable of high density recording, and is thus suitable for use in the manufacturing of various volume hologram-type optical recording media capable of high-density image recording.

Although the present invention has been described in considerable detail with regard to certain versions thereof, other versions are possible, and alterations, permutations and equivalents of the version shown will become apparent to those skilled in the art upon a reading of the specification and study of the drawings. Also, the various features of the versions herein can be combined in various ways to provide additional versions of the present invention. Furthermore, certain terminology has been used for the purposes of descriptive clarity, and not to limit the present invention. Therefore, any appended claims should not be limited to the description of the preferred versions contained herein and should include all such alterations, permutations, and equivalents as fall within the true spirit and scope of the present invention.

Having now fully described this invention, it will be understood to those of ordinary skill in the art that the methods of the present invention can be carried out with a wide and equivalent range of conditions, formulations, and other parameters without departing from the scope of the invention or any embodiments thereof.

All patents and publications cited herein are hereby fully incorporated by reference in their entirety. The citation of any publication is for its disclosure prior to the filing date and should not be construed as an admission that such publication is prior art or that the present invention is not entitled to antedate such publication by virtue of prior invention.

Unless otherwise stated, a reference to a compound or component includes the compound or component by itself, as well as in combination with other compounds or components, such as mixtures of compounds.

As used herein, the singular forms “a,” “an,” and “the” include the plural reference unless the context clearly dictates otherwise.

Except where otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in the following specification and attached claims are approximations that may vary depending upon the desired properties sought to be obtained by the present invention. At the very least, and not to be considered as an attempt to limit the application of the doctrine of equivalents to the scope of the claims, each numerical parameter should be construed in light of the number of significant digits and ordinary rounding conventions.

Additionally, the recitation of numerical ranges within this specification is considered to be a disclosure of all numerical values and ranges within that range. For example, if a range is from about 1 to about 50, it is deemed to include, for example, 1, 7, 34, 46.1, 23.7, or any other value or range within the range.

What is claimed is:

1. An optical recording composition comprising a compound denoted by general formula (I). 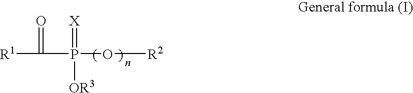
In general formula (I), each of R¹, R², and R³ independently denotes an alkyl group, aryl group, or heterocyclic group, X denotes an oxygen atom or sulfur atom, and n denotes 0 or 1.

2. The optical recording composition according to claim 1, wherein, in general formula (I), X denotes an oxygen atom.

3. The optical recording composition according to claim 1, wherein, in general formula (I), R¹ denotes an aryl group in which an alkyl group, aryl group, alkoxy group, or halogen group is present at positions 2 and/or 6.

4. The optical recording composition according to claim 1, wherein, in general formula (I), n denotes 0 and R² denotes an aryl group.

5. The optical recording composition according to claim 1, wherein, in general formula (I), n denotes 0 and R³ denotes an alkyl group.

6. The optical recording composition according to claim 1, wherein, in general formula (I), n denotes 1, and R² and/or R³ denote an alkyl group.

7. The optical recording composition according to claim 6, wherein, in general formula (I), R² and R³ denote an alkyl group.

8. The optical recording composition according to claim 1, further comprising a radical polymerizable compound.

9. The optical recording composition according to claim 1, further comprising a polyfunctional isocyanate and a polyfunctional alcohol.

10. The optical recording composition according to claim 1, which is a holographic recording composition.

11. A holographic recording medium comprising a recording layer, wherein the recording layer comprises a compound denoted by general formula (I).

12. The holographic recording medium according to claim 11, wherein, in general formula (I), X denotes an oxygen atom.

13. The holographic recording medium according to claim 11, wherein, in general formula (I), R¹ denotes an aryl group in which an alkyl group, aryl group, alkoxy group, or halogen group is present at positions 2 and/or 6.

14. The holographic recording medium according to claim 11, wherein, in general formula (1), n denotes 0 and R² denotes an aryl group.

15. The holographic recording medium according to claim 11, wherein, in general formula (1), n denotes 0 and R³ denotes an alkyl group.

16. The holographic recording medium according to claim 11, wherein, in general formula (I), n denotes 1, and R² and/or R³ denote an alkyl group.

17. The holographic recording medium according to claim 16, wherein, in general formula (I), R² and R³ denote an alkyl group.

18. The holographic recording medium according to claim 11, wherein the recording layer further comprises a radical polymerizable compound.

19. The holographic recording medium according to claim 11, wherein the recording layer further comprises a polyfunctional isocyanate and a polyfunctional alcohol.
